(19) United States
(12) Patent Application Publication
(10) Pub. No.: US 2026/0136877 A1
(43) Pub. Date: May 14, 2026

(54) METHOD OF MONITORING CHUCK PIN OF SINGLE WAFER PHOSPHORIC ACID CLEANING TOOL

(71) Applicant: Shanghai Huali Integrated Circuit Corporation, Shanghai (CN)

(72) Inventor: Lili Jia, Shanghai (CN)

(73) Assignee: Shanghai Huali Integrated Circuit Corporation, Shanghai (CN)

(21) Appl. No.: 19/184,157

(22) Filed: Apr. 21, 2025

(30) Foreign Application Priority Data
Nov. 13, 2024 (CN) 202411622786.0

(51) Int. Cl. H01L 21/67; H01L 21/306; H01L 21/66

(52) U.S. Cl. CPC H10P 72/0604; H10P 50/642; H10P 74/203

(57) ABSTRACT

The present application discloses a method of monitoring a chuck pin of a Single Wafer Phosphoric Acid Cleaning Tool, includes: step I: forming a first germanium-silicon thin film layer on a monitoring wafer, step II: clamping and fixing the monitoring wafer by a chuck pin, and performing first etching using a phosphoric acid cleaning solution, step III: measuring a first etch amount of a first germanium-silicon thin film layer in an edge region of the monitoring wafer and a fluctuation range of the first etch amount, and step IV: judging a state of the chuck pin, including: judging that the chuck pin is abnormal if the first etch amount is greater than a first set value or the fluctuation range of the first etch amount is greater than a second set value.

### CROSS-REFERENCE TO RELATED APPLICATIONS

This application claims priority to Chinese patent application No. 202411622786.0, filed on Nov. 13, 2024, the disclosure of which is incorporated herein by reference in its entirety.

### TECHNICAL FIELD

The present application relates to equipment for manufacturing semiconductor integrated circuits, in particular, to a method of monitoring a chuck pin of a Single Wafer Phosphoric Acid Cleaning Tool.

### BACKGROUND

In a process chamber of a Single Wafer Phosphoric Acid Cleaning Tool, a wafer with an upward front surface is placed on a rotatable table on which there are a plurality of chuck pins to fix a wafer position. Referring to FIG. 1, it is a top view of an interior of a process chamber of a prior-art Single Wafer Phosphoric Acid Cleaning Tool; and the process chamber includes a rotatable table structure 101 having a circumferential side where a plurality of chuck pins 102 are disposed at equal-angle interval. FIG. 1 shows 6 chuck pins 102, and the angle of the sector between two adjacent chuck pins 102 is 60 degrees. The chuck pin 102 has an opening state in which it is facilitated to pick and place a wafer such as a monitoring wafer or a product wafer and a clamped state in which a wafer can be fixed to facilitate its rotation. The wafer is driven to rotate by a rotating device of the table structure 101. When the wafer rotates, corresponding centrifugal force would evenly distribute a cleaning solution, i.e., phosphoric acid, to the surface of the wafer and throw the cleaning solution out.

As time goes, as well as an increase in an operation amount, the chuck pin 102 would be wore to some degree, and is usually replaced by setting fixed time or a fixed operation amount. However, in practical production, it is generally found that a product process has been abnormal before the time for replacing the chuck pin 12 has come. Referring to FIG. 2, it is a map diagram 103 of a film layer thickness loss of an inline product wafer after phosphoric acid cleaning is performed when a chuck pin of a prior-art Single Wafer Phosphoric Acid Cleaning Tool is abnormal; and usually, the shape of the map diagram is a shape of a practical wafer, location coordinates of the map diagram and location coordinates of the wafer correspond to each one by one, and thus, test data for corresponding positions at the map diagram represents test data for identical locations on a practical wafer. In the map diagram 103 of FIG. 2, a region corresponding to a dotted-line circle 104 is an edge region at a corresponding chuck pin 102, and it can be seen that the region corresponding to the dotted-line circle 104 has a relatively large film layer thickness loss because of the influence that the chuck pin is abnormal.

Due to a relatively large etching rate of phosphoric acid on silicon nitride, an etching rate of phosphoric acid is usually monitored by using a silicon nitride thin film as a monitoring thin film in a prior-art machine monitoring means. However, using the silicon nitride thin film as a monitoring thin film cannot accurately monitor whether the chuck pin is abnormal, and thus cannot determine the time for replacing the chuck pin. Referring to FIG. 3, it is a map diagram 105 of an etching rate (ER) of silicon nitride of an offline monitoring wafer obtained when a chuck pin of a Single Wafer Phosphoric Acid Cleaning Tool is monitored by using a silicon nitride thin film in the prior art; and as can be seen from the map diagram 105, a thickness loss of a silicon nitride thin film at a wafer edge region is uniform, independent of the position of the chuck pin 102, and therefore, silicon nitride cannot be used as a monitoring thin film to determine the time point for replacing the chuck pin 102.

### BRIEF SUMMARY

According to some embodiments in this application, a method for monitoring a chuck pin of a Single Wafer Phosphoric Acid Cleaning Tool is disclosed in the following steps:
step I. providing a monitoring wafer on which a first germanium-silicon thin film layer is formed;
step II. performing first etching on the first germanium-silicon thin film layer using a phosphoric acid cleaning solution, the monitoring wafer being clamped and fixed by the chuck pin during the first etching;
step III. measuring a first etch amount of the first germanium-silicon thin film layer in an edge region of the monitoring wafer and a fluctuation range of the first etch amount; and
step IV. judging a state of the chuck pin, including:
judging that the chuck pin is abnormal if the first etch amount is greater than a first set value or the fluctuation range of the first etch amount is greater than a second set value; and
judging that the chuck pin is normal if the first etching amount is less than or equal to the first set value and the fluctuation range of the first etching amount is less than or equal to the second set value.

In some cases, the first germanium-silicon thin film layer has a germanium concentration of 35%˜45%.

In some cases, the first germanium-silicon thin film layer has a germanium concentration of 40%.

In some cases, the first etching has etching time of 180 s˜240 s.

In some cases, in the first etching, the monitoring wafer rotates with a rotation speed of 300 rpm˜400 rpm.

In some cases, when it is judged that the chuck pin is abnormal, the operation of the Single Wafer Phosphoric Acid Cleaning Tool stops and the chuck pin is replaced.

In some cases, when it is judged that the chuck pin is normal, the Single Wafer Phosphoric Acid Cleaning Tool operates normally.

In some cases, prior to the first etching of step II, the method further includes:
pretreating a surface of the first germanium-silicon thin film layer using hydrofluoric acid.

In some cases, the monitoring wafer has a number more than one in step I.

In some cases, a frequency at which the monitoring step is performed is once a day or once in multiple days.

In some cases, the first set value is obtained by collecting a plurality of the first etch amounts and performing statistic.

The second set value is obtained by collecting fluctuation ranges for a plurality of the first etch amounts and performing statistic.

In some cases, the first set value is 25 Å.

The second set value is 13 Å.

In some cases, a plurality of the chuck pins are included in a process chamber of a Single Wafer Phosphoric Acid Cleaning Tool, and the chuck pins are disposed equidistantly on an edge of the monitoring wafer when the chuck pins fix the monitoring wafer.

In some cases, the number of the chuck pins are 6 in the process chamber of the Single Wafer Phosphoric Acid Cleaning Tool.

In some cases, the monitoring wafer includes a silicon wafer.

Unlike the prior art in which timing for replacing a chuck pin is determined by fixed time or a fixed operation amount, the present application specifically selects a germanium-silicon material, i.e., the first germanium-silicon thin film layer, as a monitoring material, the first germanium-silicon thin film layer is etched by a phosphoric acid cleaning solution, i.e., after the first etching, an etch amount at an edge region of a monitoring wafer, i.e., the first etch amount, can well reflect the state of the chuck pin, and thus the present application can accurately determine the state of the chuck pin by measuring the first etch amount and obtaining its fluctuation range, and combining pre-set first and second set values, and thus can determine the time point for replacing the chuck pin according to the abnormal state of the chuck pin. Therefore, the present application can accurately determine the time point for replacing the chuck pin, thereby preventing a product wafer abnormality to increase a product yield.

### BRIEF DESCRIPTION OF THE DRAWINGS

The present application is described in further detail below by figures and detailed description:

FIG. 1 is a top view of an interior of a process chamber of a prior-art Single Wafer Phosphoric Acid Cleaning Tool;

FIG. 2 is a map diagram of a film layer thickness loss of an inline product wafer after phosphoric acid cleaning is performed when a chuck pin of a prior-art Single Wafer Phosphoric Acid Cleaning Tool is abnormal;

FIG. 3 is a map diagram of an etching rate of silicon nitride of an offline monitoring wafer obtained when a chuck pin of a Single Wafer Phosphoric Acid Cleaning Tool is monitored by using a silicon nitride thin film in the prior art;

FIG. 4 is a flowchart of a method of monitoring a chuck pin of a Single Wafer Phosphoric Acid Cleaning Tool in an embodiment of the present application;

FIG. 5 is a flowchart of a method of monitoring a chuck pin of a Single Wafer Phosphoric Acid Cleaning Tool in a preferred embodiment of the present application;

FIG. 6A is a graph of a first etch amount obtained by collecting in a method of monitoring a chuck pin of a Single Wafer Phosphoric Acid Cleaning Tool in a preferred embodiment of the present application;

FIG. 6B is a graph of a fluctuation range of a first etch amount obtained by collecting in a method of monitoring a chuck pin of a Single Wafer Phosphoric Acid Cleaning Tool in a preferred embodiment of the present application;

FIG. 7A is a map diagram of a thickness loss of a first germanium-silicon thin film layer of a corresponding offline monitoring wafer when it is monitored that a chuck pin is abnormal in a method of monitoring a chuck pin of a Single Wafer Phosphoric Acid Cleaning Tool in a preferred embodiment of the present application;

FIG. 7B is a map diagram of a thickness loss of a first germanium-silicon thin film layer of a corresponding offline monitoring wafer after a chuck pin is replaced in a method of monitoring a chuck pin of a Single Wafer Phosphoric Acid Cleaning Tool in a preferred embodiment of the present application; and

FIG. 8 is a map diagram of a film layer thickness loss of an inline product wafer after a chuck pin is replaced in a method of monitoring a chuck pin of a Single Wafer Phosphoric Acid Cleaning Tool in a preferred embodiment of the present application.

### DETAILED DESCRIPTION OF THE DISCLOSURE

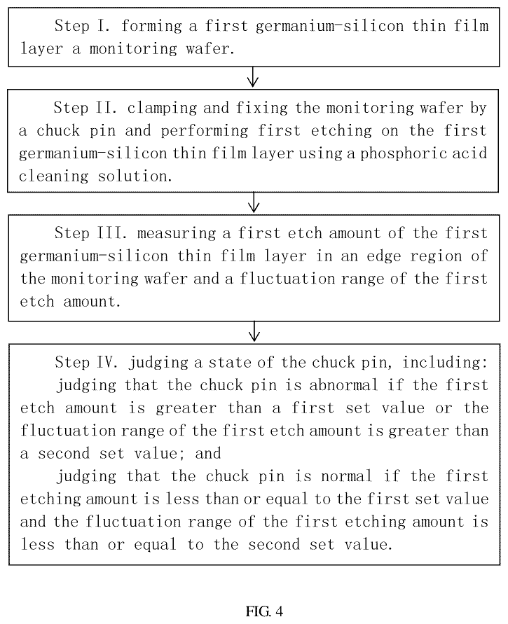

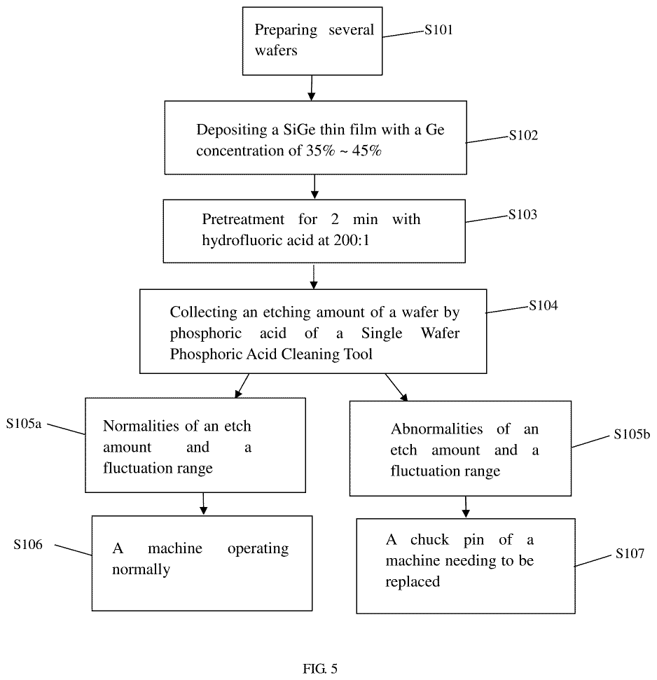

Referring to FIG. 4, it is a flowchart of a method of monitoring a chuck pin 102 of a Single Wafer Phosphoric Acid Cleaning Tool in an embodiment of the present application; and referring to FIG. 5, it is a flowchart of a method of monitoring a chuck pin 102 of a Single Wafer Phosphoric Acid Cleaning Tool in a preferred embodiment of the present application; and in the method of monitoring a chuck pin 102 of a Single Wafer Phosphoric Acid Cleaning Tool in an embodiment of the present application, the monitoring step includes:

### Step I. Providing a Monitoring Wafer.

In an embodiment of the present application, the monitoring wafer includes a silicon wafer, i.e., a circular sheet formed of monocrystalline silicon. The size of the monitoring wafer is determined according to the size of the process chamber of the chuck pin 102 of the Single Wafer Phosphoric Acid Cleaning Tool to be monitored. For example, when the size of the process chamber is adapted to a 6-inch, 8-inch, or 12-inch product wafer, a size of a corresponding monitoring wafer is also 6-inch, 8-inch, or 12-inch.

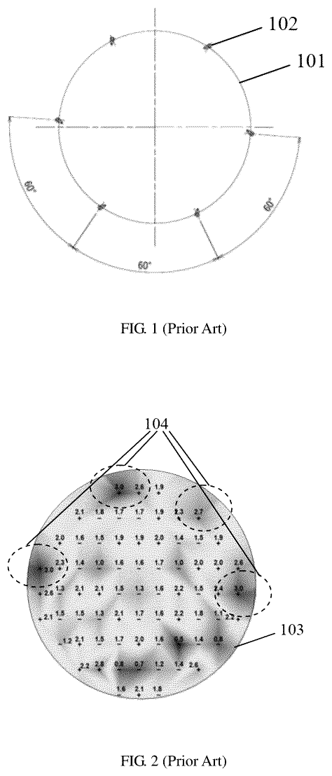

Regarding a top view of an interior of a process chamber of a Single Wafer Phosphoric Acid Cleaning Tool to be monitored in the embodiment of the present application, please also refer to FIG. 1, a plurality of the chucking pins 102 are included in the process chamber of the Single Wafer Phosphoric Acid Cleaning Tool, and the chucking pins 102 are disposed equidistantly on the edge of the monitoring wafer when the chucking pins 102 fix the monitoring wafers. In FIG. 1, a table structure 101 for placing wafers is shown, and a plurality of chuck pins 102 are disposed at equal-angle interval around the circumferential side of the table structure 101. 6 chuck pins 102 are shown in FIG. 1, and the angle of the sector between two adjacent chuck pins 102 is 60 degrees. In other embodiments, the number of chuck pins 102 can also be set differently from 6 as desired.

The chuck pin 102 has an opening state in which it is facilitated to pick and place a wafer such as a monitoring wafer or a product wafer and a clamped state in which a wafer can be fixed to facilitate its rotation. The wafer is driven to rotate by a rotating device of the table structure 101. When the wafer rotates, corresponding centrifugal force would evenly distribute a cleaning solution, i.e., phosphoric acid, to the surface of the wafer and throw the cleaning solution out. In some examples, the chuck pin 102 achieves clamping by directly utilizing centrifugal force. In other examples, the chuck pin 102 can also control an open state and a clamped state by a cylinder and a linkage device.

Referring to FIG. 5, in some preferred embodiments, the monitoring wafer has a number more than one, and the step of providing the monitoring wafer corresponds to step S101. providing several wafers in FIG. 5, the wafer here being the monitoring wafer, not a product wafer. In the product wafer, a semiconductor device structure corresponding to a product is usually formed, while in the monitoring wafer, a bare wafer without any formed structure is used.

Afterwards, on the monitoring wafer, a first germanium-silicon thin film layer is formed.

In some preferred embodiments, the first germanium-silicon thin film layer has a germanium concentration of 35%˜45%. Referring to FIG. 5, the step corresponds to step S102. depositing a SiGe thin film with a Ge concentration of 35%˜45%, the SiGe thin film being the first germanium-silicon thin film. As a more preferred alternative, the first germanium-silicon thin film layer has a Ge concentration of 40%.

In some embodiments, before performing first etching of subsequent step II, the method further includes:
pretreating a surface of the first germanium-silicon thin film layer using hydrofluoric acid.

The pretreatment is mainly used to remove a natural oxide layer on the surface of the first germanium-silicon thin film layer. In some preferred embodiments, for the hydrofluoric acid, diluted hydrofluoric acid (DHF) at 200:1 is used, and time for the pretreatment is 2 minutes. The step corresponds to step S103, pretreatment for 2 min with hydrofluoric acid at 200:1 in FIG. 5.

The method includes step II. performing first etching on the first germanium-silicon thin film layer using a phosphoric acid cleaning solution, the monitoring wafer being clamped and fixed by the chuck pin 102 during the first etching.

In some embodiments, etching time for the first etching is 180 s˜240 s.

In the first etching, the monitoring wafer rotates with a rotation speed of 300 rpm˜400 rpm.

The method includes step III. measuring a first etch amount of the first germanium-silicon thin film layer in an edge region of the monitoring wafer and a fluctuation range of the first etch amount.

In some preferred embodiments, step II and step III correspond to step S104. collecting an etching amount of a wafer by phosphoric acid of a Single Wafer Phosphoric Acid Cleaning Tool.

The method includes step IV judging a state of the chuck pin 102, including:
judging that the chuck pin 102 is abnormal if the first etch amount is greater than a first set value or the fluctuation range of the first etch amount is greater than a second set value. That is, when any one of conditions of the first etch amount being greater than the first set value and the fluctuation range of the first etch amount being greater than the second set value is satisfied, it is indicated that the chuck pin 102 is abnormal. In the preferred embodiment shown in FIG. 5, the step corresponds to step S105b, abnormalities of an etch amount and a fluctuation range in FIG. 5.

Step IV also includes judging that the chuck pin 102 is normal if the first etching amount is less than or equal to the first set value and the fluctuation range of the first etching amount is less than or equal to the second set value. In the preferred embodiment shown in FIG. 5, the step corresponds to step S105a, normalities of an etch amount and a fluctuation range in FIG. 5.

In an embodiment of the application, the first set value is obtained by collecting a plurality of the first etch amounts and performing statistic. The second set value is obtained by collecting fluctuation ranges of a plurality of the first etch amounts and performing statistic. In some examples, the first set value is 25 Å; and the second set value is 13 Å.

In an embodiment of the present application, when it is judged that the chuck pin 102 is abnormal, the operation of the Single Wafer Phosphoric Acid Cleaning Tool stops and the chuck pin 102 is replaced. In the preferred embodiment shown in FIG. 5, the step corresponds to step S107, a chuck pin of a machine needing to be replaced. The machine here is the Single Wafer Phosphoric Acid Cleaning Tool.

When it is judged that the chuck pin 102 is normal, the Single Wafer Phosphoric Acid Cleaning Tool operates normally. In the preferred embodiment shown in FIG. 5, the step corresponds to step S106, a machine operating normally.

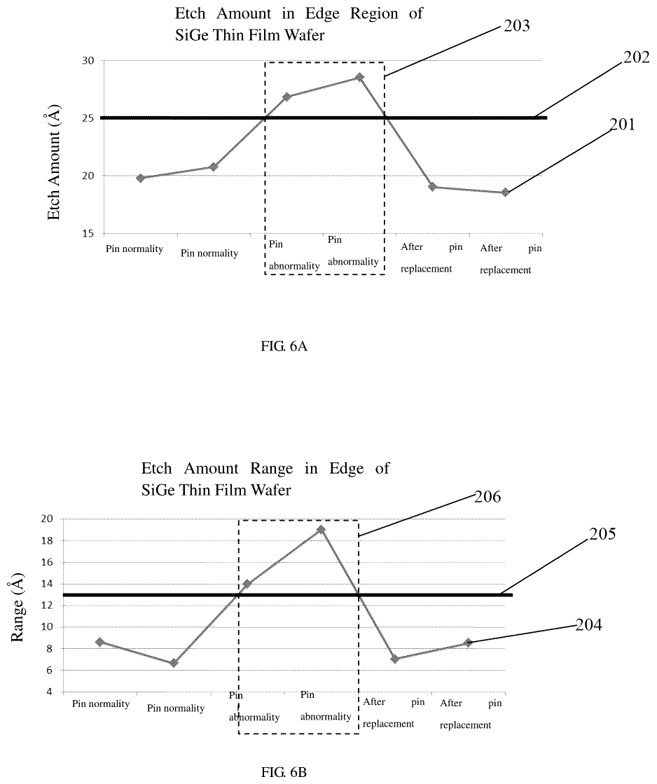

Referring to FIG. 6A, it is a graph of a first etch amount obtained by collecting in a method of monitoring a chuck pin of a Single Wafer Phosphoric Acid Cleaning Tool in a preferred embodiment of the present application; a curve 201 is the curve of the first etching amount obtained by collecting, i.e., the curve of an etching amount at an edge of an SiGe thin film wafer, the etching amount on the longitudinal coordinates is the first etching amount, the curve 201 is formed by connecting a plurality of points, and the horizontal coordinate corresponds to the states of the chuck pin 102 corresponding the first etch amounts collected at different time. A straight line 202 with a vertical coordinate of 25 Å is a straight line corresponding to the first set value, and it can be seen that the curve 201 lies above the straight line 202 in the region corresponding to the dotted-line box 203, so it is judged that the corresponding chuck pin 102 is abnormal, i.e., the pin abnormality shown in FIG. 6A. When the pin abnormality is monitored, the chuck pin 102 needs to be replaced. It can be seen that the region before the dotted-line box 203 is the region where the chuck pin 102 is normal, i.e., pin normality, and the region after the dotted-line box 203 is the region where a normal state is restored again after the chuck pin 102 is replaced, i.e., the region after pin replacement.

Referring to FIG. 6B, it is a graph of a fluctuation range of a first etch amount obtained by collecting in a method of monitoring a chuck pin of a Single Wafer Phosphoric Acid Cleaning Tool in a preferred embodiment of the present application; and a curve 204 is the curve of the fluctuation range of the first etch amount, i.e., the curve of the etch amount at the edge of the SiGe thin film wafer, Range on the vertical coordinate is the fluctuation range of the first etch amount, the curve 204 is formed by connecting a plurality of points, the horizontal coordinate correspond to the states of the chuck pin 102 corresponding to the fluctuation ranges of the first etch amounts collected at different time. The straight line 205 with a vertical coordinate of 13 Å is a straight line corresponding to the second set value, and it can be seen that the curve 204 lies above the straight line 205 in the region corresponding to the dotted-line box 206, so it is judged that the corresponding chuck pin 102 is abnormal i.e., the pin abnormality as illustrated in FIG. 6B. When the pin abnormality is monitored, the chuck pin 102 needs to be replaced. It can be seen that the region before the dotted-line box 206 is the region where the chuck pin 102 is normal, i.e., the pin normality, and the region after the dotted-line box 206 is the region where a normal state is restored again after the chuck pin 102 is replaced, i.e., the region after pin replacement.

In an embodiment of the present application, a frequency at which the monitoring step is performed is once a day or once in multiple days. In other embodiments, the frequency at which the monitoring step is performed can also be set as desired. For example, the frequency of the monitoring step can be set in relation to operation time or an operation amount, and when the operation time or operation amount increases, a wear degree of the chuck pin 102 increases and the probability of generating an abnormality increases, and at this point, the frequency at which the monitoring step is performed can be increased as needed; and vice versa.

Unlike the prior art in which timing for replacing the chuck pin 102 is determined by fixed time or a fixed operation amount, the embodiment of the present application specifically selects a germanium-silicon material, i.e., the first germanium-silicon thin film layer, as a monitoring material, the first germanium-silicon thin film layer is etched by a phosphoric acid cleaning solution, i.e., after the first etching, an etch amount at an edge region of a monitoring wafer, i.e., the first etch amount, can well reflect the state of the chuck pin 102, and thus the embodiment of the present application can accurately determine the state of the chuck pin 102 by measuring the first etch amount and obtaining its fluctuation range, and combining pre-set first and second set values, and thus can determine the time point for replacing the chuck pin 102 according to the abnormal state of the chuck pin 102. Therefore, the present application can accurately determine the time point for replacing the chuck pin 102, thereby preventing a product wafer abnormality to increase a product yield.

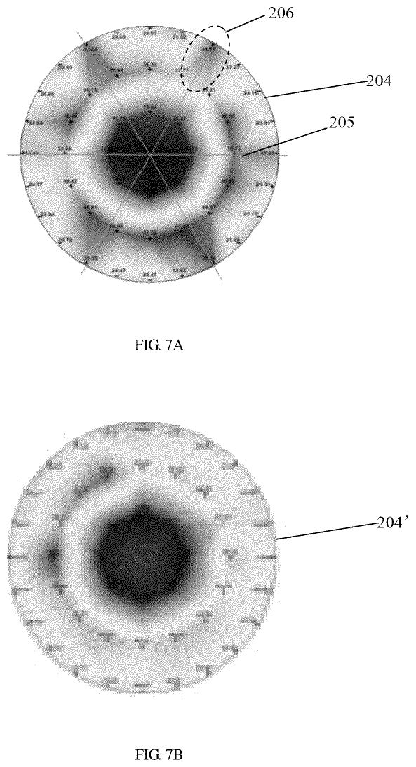

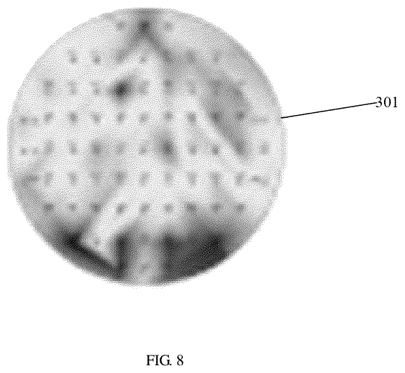

Referring to FIG. 7A, it is a map diagram 204 of a thickness loss of a first germanium-silicon thin film layer of a corresponding offline monitoring wafer when it is monitored that a chuck pin is abnormal in a method of monitoring a chuck pin of a Single Wafer Phosphoric Acid Cleaning Tool in a preferred embodiment of the present application, and the location of the corresponding measurement data in the map diagram 204 corresponds one by one to the location in the practical monitoring wafer. In FIG. 7A, each of 3 straight lines 205 corresponds to the connecting line of two chuck pins 102 located on the same diameter, and it can be seen that the thickness loss of the first germanium-silicon thin film layer increases in the edge region of the location where respective chuck pins 102 corresponding to the dotted-line circle 206 are located, so that it can also be judged that the chuck pin 102 is abnormal, and thus it can be judged that the chuck pins 102 needs to be replaced.

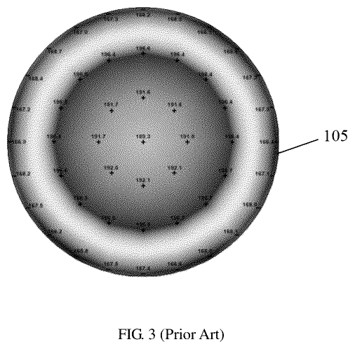

In the prior-art method, referring to FIG. 3, when silicon nitride is used as the monitoring thin film, when an abnormality of the chuck pin 102 occurs, a thickness loss in an edge region is uniform and is not related to the position of the chuck pin 102, so it is not possible to determine a time point for replacing the chuck pin 102 by adopting silicon nitride as the monitoring thin film. The prior-art method can only determine the time point for replacing the chuck pin 102 by using fixed time or a fixed operation amount, which, however, may enable that the abnormality of the chuck pin 102 has occurred before the fixed time or fixed operation amount has been reached, having an influence on a product. Further, some of the chuck pins 102, which are still normal after the fixed time or fixed operation amount has been reached, are replaced, leading to relatively premature replacement, and when normal chuck pins 102 are replaced, obviously, a cost would increase; and, a performed replacement operation needs shutdown of a machine, reducing operation time of the machine to affect operation efficiency, and also relatively increasing a cost. With the method of the embodiment of the present application, the time for replacing the chuck pin 102 can be determined appropriately, without in-advance replacement, thus avoiding an influence on a production capacity and reducing a cost, and also without delayed replacement, thus avoiding an adverse influence on a product, and guaranteeing a product yield.

Referring to FIG. 7B, it is a map diagram 204′ of a thickness loss of a first germanium-silicon thin film layer of a corresponding offline monitoring wafer after a chuck pin is replaced in a method of monitoring a chuck pin of a Single Wafer Phosphoric Acid Cleaning Tool in a preferred embodiment of the present application; and it can be seen that the thickness loss amounts of the first germanium-silicon thin film layer in the edge region of the map diagram 204′ are evenly distributed, without the phenomenon that an increase in a thickness loss occurs at the chuck pin 102, so that the chuck pin 102 after replacement is normal and does not have an adverse influence on a product.

Referring to FIG. 8, it is a map diagram 301 of a film layer thickness loss of an inline product wafer after a chuck pin is replaced in a method of monitoring a chuck pin of a Single Wafer Phosphoric Acid Cleaning Tool in a preferred embodiment of the present application, the map diagram 301 corresponds to a distribution graph of a film layer thickness loss, corresponding to a practical inline product wafer, on a product wafer, and it can be seen that the film layer thickness loss of the inline product wafers is uniformly distributed, without the phenomenon that the film layer thickness loss increases in the edge region at the chuck pin 102 shown by the dotted-line circle 104 in the distribution graph, corresponding to the map diagram 103 of FIG. 2, of the film layer thickness loss of the inline product wafer, so the inline product wafer is normal and is not affected by the abnormality of the chuck pin 102.

The present application is described in detail above by specific embodiments which do not constitute a limitation on the present application. Without departing from the principle of the present application, those skilled in the art may also make many changes and improvements which should also be regarded as the scope of protection of the present application.

What is claimed is:

1. A method of monitoring a chuck pin of a single wafer phosphoric acid cleaning tool, wherein the method comprises:
step I: providing a monitoring wafer on which a first germanium-silicon thin film layer is formed;
step II: performing first etching on the first germanium-silicon thin film layer using a phosphoric acid cleaning solution, the monitoring wafer being clamped and fixed by the chuck pin during the first etching;
step III: measuring a first etch amount of the first germanium-silicon thin film layer in an edge region of the monitoring wafer and a fluctuation range of the first etch amount; and
step IV: judging a state of the chuck pin, comprising:
judging that the chuck pin is abnormal if the first etch amount is greater than a first set value or the fluctuation range of the first etch amount is greater than a second set value; and
judging that the chuck pin is normal if the first etching amount is less than or equal to the first set value and the fluctuation range of the first etching amount is less than or equal to the second set value.

2. The method of monitoring the chuck pin of the single wafer phosphoric acid cleaning tool according to claim 1, wherein the first germanium-silicon thin film layer has a germanium concentration of 35%˜45%.

3. The method of monitoring the chuck pin of the single wafer phosphoric acid cleaning tool according to claim 2, wherein the first germanium-silicon thin film layer has a germanium concentration of 40%.

4. The method of monitoring the chuck pin of the single wafer phosphoric acid cleaning tool according to claim 1, wherein the first etching has an etching time of 180 s˜240 s.

5. The method of monitoring the chuck pin of the single wafer phosphoric acid cleaning tool according to claim 4, wherein in the first etching, the monitoring wafer rotates with a rotation speed of 300 rpm˜400 rpm.

6. The method of monitoring the chuck pin of the single wafer phosphoric acid cleaning tool according to claim 1, wherein, when it is judged that the chuck pin is abnormal, operation of the single wafer phosphoric acid cleaning tool stops and the chuck pin is replaced.

7. The method of monitoring the chuck pin of the single wafer phosphoric acid cleaning tool according to claim 1, wherein, when it is judged that the chuck pin is normal, the single wafer phosphoric acid cleaning tool operates normally.

8. The method of monitoring the chuck pin of the single wafer phosphoric acid cleaning tool according to claim 1, wherein, prior to the performing the first etching, the method further comprises:
pre-treating a surface of the first germanium-silicon thin film layer using hydrofluoric acid.

9. The method of monitoring the chuck pin of the single wafer phosphoric acid cleaning tool according to claim 1, wherein the monitoring wafer has a number more than one in step I.

10. The method of monitoring the chuck pin of the single wafer phosphoric acid cleaning tool according to claim 1, wherein a frequency at which the method is performed is once a day or once in multiple days.

11. The method of monitoring the chuck pin of the single wafer phosphoric acid cleaning tool according to claim 1, wherein the first set value is obtained by collecting a plurality of first etch amounts and performing a statistic; and
the second set value is obtained by collecting fluctuation ranges for the plurality of the first etch amounts and performing a statistic.

12. The method of monitoring the chuck pin of the single wafer phosphoric acid cleaning tool according to claim 11, wherein the first set value is 25 Å and the second set value is 13 Å.

13. The method of monitoring the chuck pin of the single wafer phosphoric acid cleaning tool according to claim 1, wherein a plurality of chuck pins are included in a process chamber of the single wafer phosphoric acid cleaning tool, and the chuck pins are disposed equidistantly on an edge of the monitoring wafer when the chuck pins fix the monitoring wafer.

14. The method of monitoring the chuck pin of the single wafer phosphoric acid cleaning tool according to claim 13, wherein a number of the chuck pins is 6 in the process chamber of the single wafer phosphoric acid cleaning tool.

15. The method of monitoring the chuck pin of the single wafer phosphoric acid cleaning tool according to claim 1, wherein the monitoring wafer comprises a silicon wafer.
